(19) United States
(12) Patent Application Publication
(10) Pub. No.: US 2026/0204333 A1
(43) Pub. Date: Jul. 16, 2026

(54) DATA WRITING METHOD AND MEMORY CONTROLLER

(71) Applicant: Hefei Kaimeng Technology Co., Ltd., Anhui (CN)

(72) Inventors: Yang Chen, Anhui (CN); Kuai Cao, Anhui (CN); Tsung-Lin Wu, Anhui (CN); Qiao ZHU, Anhui (CN); Dong Dong Yao, Anhui (CN); Dong Sheng RAO, Anhui (CN)

(73) Assignee: Hefei Kaimeng Technology Co., Ltd., Anhui (CN)

(21) Appl. No.: 19/411,381

(22) Filed: Dec. 8, 2025

(30) Foreign Application Priority Data
Jan. 15, 2025 (CN) 202510064948.1

(51) Int. Cl. G11C 16/34; G11C 16/10

(52) U.S. Cl. CPC G11C 16/3495; G11C 16/102; G11C 16/3459

(57) ABSTRACT

The present disclosure provides a data writing method and a memory controller, adapted for a rewritable non-volatile memory module having a plurality of memory cells. The method comprises the following steps: first, obtaining original data from a host system. Then, performing a plurality of randomization operations on the original data to obtain a plurality of write data. Next, based on a plurality of directions of a three-dimensional circuit architecture of the rewritable non-volatile memory module, performing a randomization verification operation on each write data to obtain a target write data from the plurality of write data, wherein a quality of randomization of the target write data is determined to be qualified. Finally, storing the target write data into a plurality of target memory cells among the plurality of memory cells. Through multiple randomization operations and a verification process, the present disclosure effectively improves the randomness and reliability of data storage.

### CROSS-REFERENCE TO RELATED APPLICATION

This application claims the priority benefit of China application serial no. 202510064948.1, filed on Jan. 15, 2025. The entirety of the above-mentioned patent application is hereby incorporated by reference herein and made a part of this specification.

### BACKGROUND

### Technical Field

The present disclosure relates to the field of semiconductor memory technology, and more particularly, to a data writing method for a rewritable non-volatile memory module and a memory controller using the method.

### Description of Related Art

With the rapid development of information technology, non-volatile storage devices are increasingly widely used in various electronic products. In particular, three-dimensional NAND flash memory has become the mainstream of current non-volatile memory technology due to its high storage density, low cost, and excellent performance. However, as storage density continues to increase, issues of data reliability and interference between memory cells have become more prominent.

To improve the reliability of data storage and reduce interference between cells, data randomization technology is widely used in NAND flash memory. Traditional data randomization methods typically employ a single randomization algorithm, such as a simple XOR operation or a fixed permutation table. Although this method improves data distribution to some extent, its effectiveness is often unsatisfactory when facing increasingly complex three-dimensional NAND flash memory structures.

Furthermore, the related art generally lacks an effective verification mechanism for randomization results. Writing data directly without verifying the quality of the randomization may result in an uneven distribution of certain data patterns in a memory, so as to affect storage performance and reliability. Especially in high-density storage scenarios, improper data distribution may lead to problems such as read disturbance and write disturbance, which in turn shortens the service life of a storage device.

### SUMMARY

An objective of the present disclosure is to solve the aforementioned problems, by being able to perform a plurality of randomization operations and effectively verify the quality of the randomization, to ensure that data written into a memory has good random distribution characteristics, so as to improve the reliability and performance of storage.

One or more embodiments of the present disclosure provide a data writing method for a rewritable non-volatile memory module having a plurality of memory cells. The method comprises: obtaining original data from a host system; performing a plurality of randomization operations on the original data to obtain a plurality of write data; based on a plurality of directions of a three-dimensional circuit architecture of the rewritable non-volatile memory module, performing a randomization verification operation on each write data to obtain a target write data from the plurality of write data, wherein a quality of randomization of the target write data is determined to be qualified; and storing the target write data into a plurality of target memory cells among the plurality of memory cells.

One or more embodiments of the present disclosure provide a memory controller, adapted for a storage device configured with a rewritable non-volatile memory module, wherein the storage device is electrically connected to a host system. The memory controller comprises: a memory interface control circuit, for electrically connecting to the rewritable non-volatile memory module, wherein the rewritable non-volatile memory module has a plurality of memory cells; and a processor, electrically connected to the memory interface control circuit. The processor is configured to: obtain original data from the host system; perform a plurality of randomization operations on the original data to obtain a plurality of write data; based on a plurality of directions of a three-dimensional circuit architecture of the rewritable non-volatile memory module, perform a randomization verification operation on each write data to obtain a target write data from the plurality of write data, wherein a quality of randomization of the target write data is determined to be qualified; and store the target write data into a plurality of target memory cells among the plurality of memory cells.

Based on the above, the data writing method and its randomization verification operation proposed by the present disclosure have significant technical effects in a three-dimensional structure non-volatile memory. By performing multiple randomization operations on write data and executing a verification process based on a plurality of directions of a three-dimensional circuit architecture, the method can effectively improve the distribution uniformity of data in the memory.

To make the aforementioned more comprehensible, several embodiments accompanied with drawings are described in detail as follows.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a block diagram of a host system and a storage device according to an embodiment of the present disclosure.

FIG. 2 is a flow chart of a data writing method according to an embodiment of the present disclosure.

FIG. 3 is a schematic diagram of randomization operations according to an embodiment of the present disclosure.

FIG. 4 is a schematic diagram of a three-dimensional circuit architecture of a plurality of memory cells of a rewritable non-volatile memory module according to an embodiment of the present disclosure.

FIG. 5 is a flow chart of a randomization verification operation according to an embodiment of the present disclosure.

### DESCRIPTION OF THE EMBODIMENTS

Reference will now be made in detail to exemplary embodiments of the present disclosure, examples of which are illustrated in the accompanying drawings. Wherever possible, the same reference symbols are used in the drawings and the description to refer to the same or like parts.

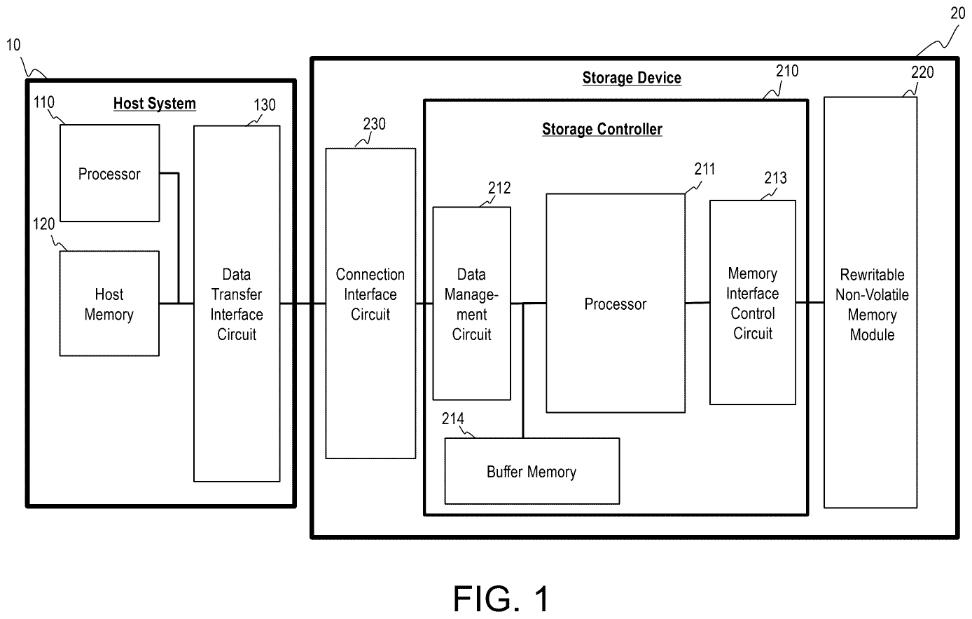

FIG. 1 is a block diagram of a host system and a storage device according to an embodiment of the present disclosure. Please refer to FIG. 1, host system 10 is, for example, a personal computer, a laptop computer, or a server. Host system 10 includes processor 110 (also referred to as a second processor), host memory 120, and data transfer interface circuit 130. In an embodiment, processor 110 is coupled (also referred to as electrically connected) to host memory 120 and data transfer interface circuit 130. In another embodiment, processor 110, host memory 120, and data transfer interface circuit 130 are electrically connected to each other via a system bus. In an embodiment, processor 110, host memory 120, and data transfer interface circuit 130 may be disposed on a motherboard of host system 10. In an embodiment, the original data is, for example, user data transmitted from host system 10 to storage device 20, or data on which randomization operations has not yet been performed.

Storage device 20 includes memory controller 210, rewritable non-volatile memory module 220, and connection interface circuit 230. Memory controller 210 includes processor 211 (also referred to as a first processor), data management circuit 212, and memory interface control circuit 213.

In an embodiment, host system 10 is electrically connected to storage device 20 through data transfer interface circuit 130 and connection interface circuit 230 of storage device 20 to perform data access operations. For example, host system 10 may store data to storage device 20 or read data from storage device 20 via data transfer interface circuit 130.

In an embodiment, a number of data transfer interface circuits 130 can be one or a plurality of. Through data transfer interface circuit 130, a motherboard may be electrically connected to storage device 20 via wired or wireless means. Storage device 20 may be, for example, a USB flash drive, a memory card, a solid state drive (SSD), or a wireless memory storage device. Wireless memory storage devices may be, for example, near field communication (NFC) memory storage devices, wireless fidelity (WiFi) memory storage devices, Bluetooth memory storage devices, or low-power Bluetooth memory storage devices (e.g., iBeacon), etc., which are memory storage devices based on various wireless communication technologies. In addition, a motherboard may also be electrically connected to various I/O devices such as a global positioning system (GPS) module, network interface cards, wireless transmission devices, keyboards, screens, speakers, etc. through a system bus.

In an embodiment, data transfer interface circuit 130 and connection interface circuit 230 are interface circuits compatible with the Peripheral Component Interconnect Express (PCI Express) standard. Moreover, data transfer interface circuit 130 and connection interface circuit 230 transmit data using Non-Volatile Memory Express (NVMe) communication protocol.

Furthermore, in another embodiment, connection interface circuit 230 may be packaged in a chip together with memory controller 210, or connection interface circuit 230 may be disposed outside a chip that includes memory controller 210.

In an embodiment, host memory 120 is used to temporarily store instructions or data executed by processor 110. For example, in an embodiment, host memory 120 may be Dynamic Random Access Memory (DRAM), Static Random Access Memory (SRAM), etc. However, it must be understood that the present disclosure is not limited thereto, and host memory 120 may also be other suitable memory.

Memory controller 210 is used to execute a plurality of logic gates or control instructions implemented in hardware or firmware form and to perform data writing, reading, and erasing operations in rewritable non-volatile memory module 220 according to instructions from host system 10.

More specifically, processor 211 in memory controller 210 is hardware with computing capability, which is used to control overall operations of memory controller 210. Specifically, processor 211 is programmed by a plurality of control instructions/program codes, and when storage device 20 operates, these control instructions/program codes are executed to perform data writing, reading, and erasing operations. Furthermore, in an embodiment, the control instructions/program codes may be further executed to perform data writing operations, randomization verification operations, or randomization operations, so as to implement the data writing method provided by the present disclosure. Control instructions/program codes corresponding to the data writing method may be further implemented as circuit units in hardware form, so as to implement the data writing method provided by the present disclosure.

It is worth mentioning that, in an embodiment, processor 110 and processor 211 are, for example, Central Processing Unit (CPU), microprocessor, or other programmable processing units, Digital Signal Processor (DSP), programmable controller, Application Specific Integrated Circuits (ASIC), Programmable Logic Device (PLD), or other similar circuit components. The present disclosure is not limited thereto.

In an embodiment, as described above, memory controller 210 further includes data management circuit 212 and memory interface control circuit 213. It should be noted that operations performed by various components of memory controller 210 may also be regarded as operations performed by memory controller 210.

Data management circuit 212 is electrically connected to processor 211, memory interface control circuit 213, and connection interface circuit 230. Data management circuit 212 is used to accept instructions from processor 211 to perform data transmission. For example, reading data from host system 10 (e.g., host memory 120) via connection interface circuit 230, and writing the read data to rewritable non-volatile memory module 220 via memory interface control circuit 213 (e.g., performing write operations according to write instructions from host system 10). For another example, reading data from one or more physical units of rewritable non-volatile memory module 220 via memory interface control circuit 213 (data may be read from one or more memory cells in one or more physical units), and writing the read data to host system 10 (e.g., host memory 120) via connection interface circuit 230 (e.g., performing read operations according to read instructions from host system 10). In another embodiment, data management circuit 212 may also be integrated into processor 211.

Memory interface control circuit 213 is used to accept instructions from processor 211 and cooperate with data management circuit 212 to perform writing (also referred to as programming) operations, read operations, or erase operations on rewritable non-volatile memory module 220.

Furthermore, data to be written to rewritable non-volatile memory module 220 is converted to a format acceptable by rewritable non-volatile memory module 220 via memory interface control circuit 213. Specifically, if processor 211 wants to access rewritable non-volatile memory module 220, processor 211 transmits corresponding instruction sequences to memory interface control circuit 213 to instruct memory interface control circuit 213 to perform corresponding operations. For example, these instruction sequences may include write instruction sequences for instructing writing of data, read instruction sequences for instructing reading of data, erase instruction sequences for instructing erasing of data, and corresponding instruction sequences for instructing various memory operations. These instruction sequences may include one or more signals, or data on a bus. These signals or data may include instruction codes or program codes. For example, in a read instruction sequence, information such as a read identification code, a memory address, and a physical address is included.

Furthermore, memory controller 210 establishes a logical-to-physical address mapping table and a physical-to-logical address mapping table to record mapping relationships between logical addresses of logical units (e.g., logical blocks, logical pages) allocated to rewritable non-volatile memory module 220 and physical addresses of physical units (e.g., physical erase units/physical blocks, physical pages). In other words, memory controller 210 can find a physical unit mapped by a logical unit through the logical-to-physical address mapping table (also referred to as logical-to-physical mapping table) (e.g., finding a physical page mapped by a logical page; finding a physical address mapped by a logical address), and memory controller 210 can find a logical unit mapped by a physical unit through the physical-to-logical address mapping table (also referred to as physical-to-logical mapping table) (e.g., finding a logical page mapped by a physical page; finding a logical address mapped by a physical address).

In an embodiment, memory controller 210 further includes buffer memory 214. Buffer memory is electrically connected to processor 211 and is used to temporarily store data and instructions from host system 10, data from rewritable non-volatile memory module 220, or other system data for managing storage device 20 (e.g., various mapping tables, index tables, various information or data related to randomization operations and randomization verification operations), so that processor 211 can quickly access the data, instructions, or system data from buffer memory 214. In an embodiment, memory controller 210 may establish one or more write mapping tables in buffer memory 214 to indicate target physical addresses to which valid data is to be written. It should be noted that, in other embodiments, buffer memory 214 may also be configured outside memory controller 210. Alternatively, buffer memory 214 may be configured both inside and outside memory controller 210.

Rewritable non-volatile memory module 220 is electrically connected to memory controller 210 (memory interface control circuit 213) and is used to store user data sent by host system 10.

In an embodiment, each memory die (chip) of a plurality of memory dies in rewritable non-volatile memory module 220 has a plurality of planes, and each plane has a plurality of physical blocks. Each physical block includes a plurality of physical programming units (also referred to as physical pages). Each physical page has a plurality of memory groups (also referred to as physical bytes or bytes), each memory group corresponds to a physical address. A physical address is used to record the physical location of data stored in a memory group. It should be noted that the present disclosure does not limit sizes of each physical page and logical page.

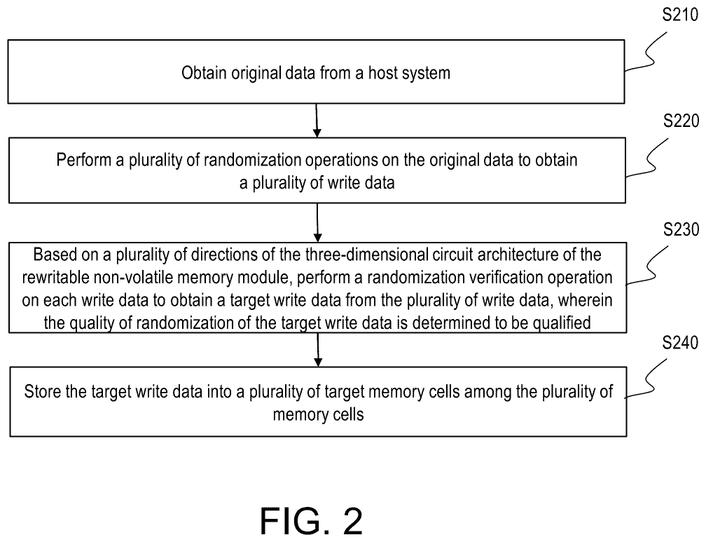

FIG. 2 is a flow chart of a data writing method according to an embodiment of the present disclosure.

Please refer to FIG. 2, in step S210, memory controller 210 (processor 211) obtains original data from host system 10. Next, in step S220, processor 211 performs a plurality of randomization operations on the original data to obtain a plurality of write data.

In an embodiment, processor 211 perform a randomization operation on original data to obtain a write data, wherein the randomization operation is used to change distribution patterns of first bit values and second bit values in the original data, so that arrangements of the first bit values and the second bit values in the write data exhibit random distribution characteristics, wherein the first bit values and the second bit values respectively correspond to “0” and “1” in binary data. After performing the randomization operation, processor 211 stores the obtained corresponding write data to buffer memory 214.

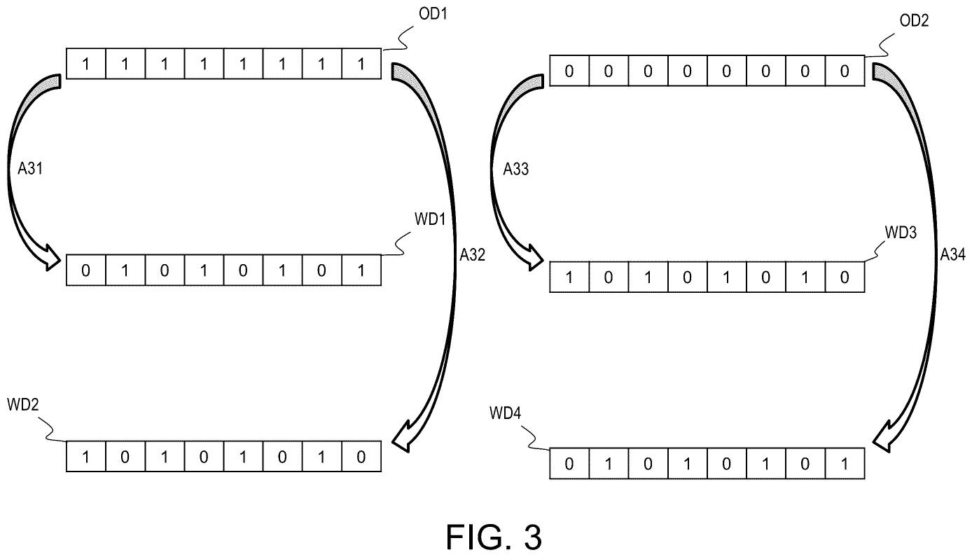

FIG. 3 is a schematic diagram of randomization operations according to an embodiment of the present disclosure. For example, randomization operations of the present disclosure can be further illustrated through a specific example. As shown in FIG. 3, the figure shows a process of performing randomization operations on original data. In this example, consider two groups of original data OD1 and OD2, each group containing 8 bits.

OD1 consists of 8 consecutive “1”s (11111111), while OD2 consists of 8 consecutive “0”s (00000000). These two groups of data represent non-random distributions under extreme conditions, wherein distributions of first bit values (“0”) and second bit values (“1”) are highly concentrated. Original data is, for example, user data that host system 10 wants to store to storage device 20.

Through performing randomization operations, corresponding write data WD1, WD2, WD3, and WD4 are obtained. Specifically:
OD1 is subjected to a first randomization operation A31 to generate WD1 (01010101).
OD1 is subjected to a second randomization operation A32 to generate WD2 (10101010).
OD2 is subjected to a third randomization operation A33 to generate WD3 (10101010).
OD2 is subjected to a fourth randomization operation A34 to generate WD4 (01010101).

From the results, it can be seen that regardless of whether original data is all “1”s or all “0”s, write data obtained after randomization operations all exhibit patterns where “0”s and “1”s appear uniformly and alternately. This pattern clearly changes original distributions of first bit values and second bit values in original data, so as to cause arrangements of “0”s and “1”s in write data exhibit more random distribution characteristics.

It is worth noting that although write data in this example exhibits regular alternating patterns, this is only for simplicity of description. In actual applications, results of randomization operations typically produce more complex and irregular bit distributions, so as to ensure security of data stored in storage devices.

Through this example, it can be clearly seen how randomization operations effectively change distribution patterns of bit values in original data, so as to achieve the purpose of data randomization. This randomization can not only improve uniformity of data storage, so as to prevent memory cells from causing write disturbance phenomena due to non-uniform distributions of bit values of data, but also enhance security of data.

More specifically, in an embodiment, a process of performing a plurality of randomization operations on original data may use different randomization algorithms to process the original data, wherein the different randomization algorithms include at least one of the following:

(1) XOR operation: A system (e.g., processor 211) predefines a plurality of groups of random sequences of different lengths, stored in lookup tables. According to a size of original data, a random sequence of an appropriate length is selected. If a length of original data exceeds the length of the random sequence, the random sequence is used cyclically. When performing an XOR operation, each bit of original data performs an exclusive OR operation with a corresponding bit of the random sequence, generating a first type of write data.

Shift operation: A system maintains a shift amount pool, containing different cyclic shift and logical shift values. When performing a shift operation on original data, a value is selected from the shift amount pool to shift an entire data block. For a large data block, it can be divided into segments of fixed size, each segment uses a different shift amount, and then the segments are recombined, generating a second type of write data.

Permutation operation: A system predefines a plurality of permutation tables, each permutation table defines different bit reordering methods. A permutation table is selected, and bits in original data are rearranged according to an order defined in the table. For a large data block, it can be divided into blocks of fixed size, each block uses a different permutation table, and then the blocks are recombined, generating a third type of write data.

Dynamic random seed operation: A system collects a plurality of system variables as a random seed input, including but not limited to: system time (including local time of host system 10 or storage device 20), a data address, temperature sensor readings, power supply voltage fluctuation values, operating frequency of memory controller 210, recent numbers of data read/write operations, unique identifiers of storage device 20, process IDs or thread IDs of host system 10, MAC addresses of network interfaces (if available), current remaining capacity of storage device 20, running time since last boot, values of internal error counters of storage device 20, etc. A system may select one of these variables as a seed, or combine a plurality of variables to generate more complex seeds. For example, system time, temperature readings, and error counter values may be combined through bit operations to generate a composite seed. This seed is used to initialize a pseudo-random number generator (such as a linear congruential generator or Mersenne Twister algorithm) to produce a random sequence. Then, this random sequence is used to transform original data (such as a XOR operation or bitwise addition), generating a fourth type of write data.

(5) Grouping operation: Original data is divided into a plurality of sub-blocks, each sub-block may have a fixed size (such as 4 KB), or may be dynamically determined (such as based on entropy values of data). For each sub-block, a system selects one or more from the above four operations for combined application. For example:

The first sub-block may first undergo an XOR operation, then undergo a shift operation.

The second sub-block may first undergo permutation operations, then use dynamic random seed operations.

The third sub-block may only undergo dynamic random seed operations.

After processing all sub-blocks, the sub-blocks are recombined to form a fifth type of write data.

Through these five different randomization operations, a system generates five different types of write data. This diversified randomization strategy increases randomness of data, so that the distribution of bit states of bit values of finally generated write data is more uniform.

Please return to FIG. 2. Next, in step S230, processor 211, based on a plurality of directions of a three-dimensional circuit architecture of the rewritable non-volatile memory module, performs randomization verification operations on each write data to obtain target write data from the plurality of write data, wherein a quality of randomization of the target write data is determined to be qualified.

Before the details of the randomization verification operation are explained, first explain a three-dimensional circuit architecture of a plurality of memory cells of the rewritable non-volatile memory module 220, wherein the plurality of memory cells are regarded as being configured at intersections of m first reference lines corresponding to X direction (also referred to as first direction), p second reference lines corresponding to Y direction (also referred to as second direction), and q third reference lines corresponding to Z direction (also referred to as third direction).

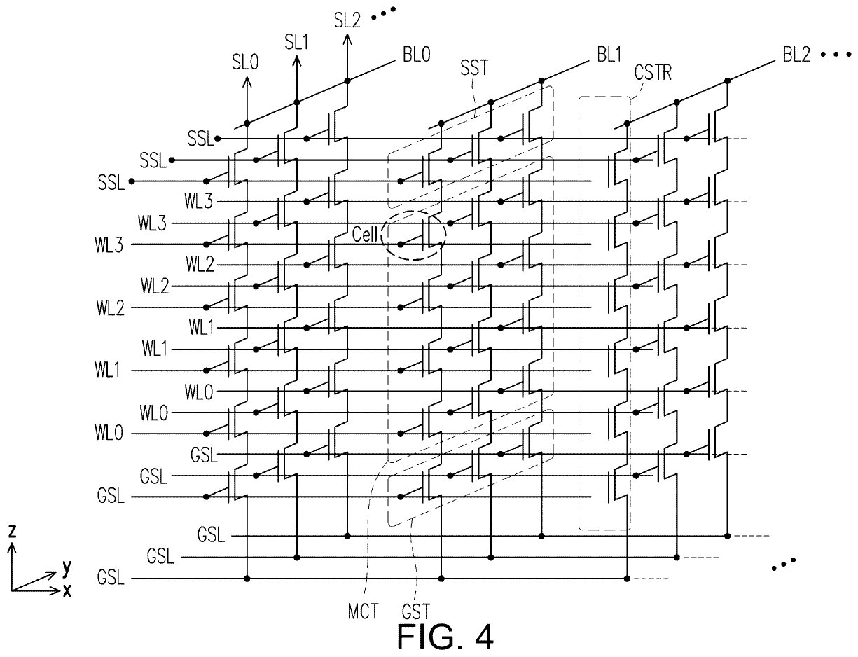

FIG. 4 is a schematic diagram of a three-dimensional circuit architecture of a plurality of memory cells of a rewritable non-volatile memory module according to an embodiment of the present disclosure. This structure contains a plurality of key components, forming a complex three-dimensional storage array. Using a NAND-type rewritable non-volatile memory module as an example, the specific structure is as follows:

Word Lines (WL): Marked as WL0, WL1, WL2, and WL3 in the figure, arranged horizontally along the x-axis direction. Each plane has a plurality of parallel word lines, used to select memory cells of specific layers. Word lines may be regarded as first reference lines corresponding to X direction (also referred to as first direction).

Bit Lines (BL): Marked as BL0, BL1, BL2, etc. in the figure, arranged vertically along y-axis direction. Bit lines may be regarded as second reference lines corresponding to Y direction (also referred to as second direction).

Cell String (CSTR): a physical structure, containing a series of vertically stacked memory cells and SST at the top and GST at the bottom. It represents a complete vertical NAND string in a three-dimensional storage array, and is a basic building block in a memory array.

String Lines (SL): Marked as SL0, SL1, SL2, etc. in the figure, arranged vertically along the z-axis direction. Each string line contains a series of vertically stacked memory cells, forming a NAND string structure. String lines may be regarded as third reference lines corresponding to Z direction (also referred to as third direction). CSTR (Cell String) in the present disclosure refers to a complete vertical structure containing a series of vertically stacked memory cells and SST at the top and GST at the bottom. Wherein, vertical memory cell stack portions inside CSTR may be referred to as String Lines.

Source Select Line (SSL): Located at the top of NAND strings, used to control source select transistors (SST).

Ground Select Line (GSL): Located at the bottom of NAND strings, used to control ground select transistors (GST).

Common Source Line (CSL): Located at the very bottom, providing common source connections for all NAND strings.

Memory Cell Transistor (MCT): Marked as MCT in the figure, is a unit that actually stores data.

Source Select Transistor (SST): Located at the top of each NAND string, controlled by SSL.

Ground Select Transistor (GST): Located at the bottom of each NAND string, controlled by GSL.

In simple terms, in this three-dimensional structure, the references for the three directions are:
X direction: Word Line (WL), first reference line;
Y direction: Bit Line (BL), second reference line;
Z direction: String Line (SL); third reference line.

Intersections of these three types of reference lines are configured as storage units, also referred to as memory cells (marked as “Cell” in the figure). Each memory cell is located at a specific intersection of WL, BL, and SL, capable of independently storing and accessing data. This three-dimensional structure significantly improves storage density, enabling more memory cells to be accommodated on the same chip area. It should be noted that these three directions are perpendicular to each other.

In an embodiment, processor 211 obtains a plurality of bit values of each write data, each of the plurality of bit values being one of preset N bit states. In the present disclosure, memory cells of non-volatile storage devices may be configured to store different amounts of bit data. A number of bits that each memory cell is configured to store may vary according to specific application requirements and technical implementations, ranging from 1 bit to multiple bits. They are divided into multiple types: SLC (Single-Level Cell), single-level cell; MLC (Multi-Level Cell), multi-level cell; TLC (Triple-Level Cell), triple-level cell; QLC (Quad-Level Cell), quad-level cell; PLC (Penta-Level Cell), penta-level cell.

Specifically, a single memory cell may be programmed to have 2^{X} different threshold voltage states, where X represents a number of bits that the memory cell is configured to store. For example, when X=1, a memory cell has two bit states and can store 1-bit data (SLC); when X=2, a memory cell has 4(2²) bit states (MLC) and can store 2-bit data; when X=3, a memory cell has a 8(2³) bit states and can store 3-bit data (TLC); when X=4, memory cell has 16(2⁴) bit states and can store 4-bit data (QLC); when X=5, a memory cell has 32(2⁵) bit states and can store 5-bit data (PLC). And so forth. This method allows storage devices to achieve different storage densities under the same physical structure, so as to achieve a balance among capacity, performance, and reliability.

Taking TLC (Triple-Level Cell) flash memory as an example, each memory cell can store 3 bits of information/data, corresponding to 8 bit states (N=2³=8), typically denoted as S0, S1, S2, S3, S4, S5, S6, and S7. Processor 211 reads a voltage level of each memory cell and converts it to corresponding a bit state. For example, a voltage level of a certain memory cell may correspond to state S3.

On the other hand, it is worth mentioning that processor 211 may identify specific positions of a plurality of memory cells used to store the plurality of bit values in a three-dimensional circuit architecture of the rewritable non-volatile memory module according to a plurality of physical addresses used to store the plurality of bit values of write data, so that processor 211 may obtain, according to these specific positions, M groups of first bit values stored on M first reference lines corresponding to first direction among the plurality of bit values in write data (e.g., M bit groups corresponding to first direction, respectively including a plurality of first bit values), obtain P groups of second bit values stored on P second reference lines corresponding to second direction among the plurality of bit values in write data (e.g., P bit groups corresponding to second direction, respectively including a plurality of second bit values), and obtain Q groups of third bit values stored on Q third reference lines corresponding to third direction among the plurality of bit values in write data (e.g., Q bit groups corresponding to third direction, respectively including a plurality of third bit values). That is, the plurality of bit values in write data may be respectively represented by M bit groups corresponding to first direction, P bit groups corresponding to second direction, or Q bit groups corresponding to third direction.

It should be noted that randomization verification operations provided by the present disclosure may first verify one of the first direction, the second direction, and the third direction, then verify the other directions. The present disclosure is not limited to the order in which directions are verified. On the other hand, the first direction is not limited to X direction, and the first direction may be X direction, Y direction, or Z direction; and the second direction and the third direction are directions other than the first direction.

In the following, a plurality of embodiments are used to illustrate implementation methods of the randomization verification operations of the present disclosure.

### Embodiment 1

According to the plurality of bit values of each bit value group, obtaining, for each bit value group, N state percentages corresponding to the N bit states.

For example, in an embodiment, assume memory cells are SLC, i.e., X=1, N=2¹=2. Processor 211 obtains a plurality of bit value groups of write data in first direction. Assume there are 4 bit value groups (M=4) in first direction, respectively corresponding to 4 first reference lines, each group containing 8 bits, specifically as follows:
1st bit value group: “10110101” (8 bits);
2nd bit value group: “11001100” (8 bits);
3rd bit value group: “10101010” (8 bits);
4th bit value group: “11110000” (8 bits).

Next, processor 211 respectively obtains state percentages of N bit states of each bit value group. In this example, N=2, representing two states (S0=0 and S1=1).

For 1st bit value group:
Number of S0 is 3, state percentage: ⅜=37.5%;
Number of S1 is 5, state percentage: ⅝=62.5%.

For 2nd bit value group:
Number of S0 is 4, state percentage: 4/8=50.0%;
Number of S1 is 4, state percentage: 4/8=50.0%.

For 3rd bit value group:
Number of S0 is 4, state percentage: 4/8=50.0%;
Number of S1 is 4, state percentage: 4/8=50.0%.

For 4th bit value group:
Number of S0 is 4, state percentage: 4/8=50.0%;
Number of S1 is 4, state percentage: 4/8=50.0%.

Through this method, processor 211 obtains, for each of the M bit value groups in the first direction, the N state percentages. These state percentage data will be used for subsequent randomization verification operations.

In this simple embodiment, processor 211 may preliminarily determine the quality of the randomization by comparing percentages of two states. If differences in percentages of two bit states are not significant, the quality of the randomization is considered good. For example, if a difference between the percentages of the two states is less than a preset threshold, it may be determined that the differences in the percentages of the two states are not significant, and the quality of the randomization is good.

In another embodiment, the present disclosure provides a plurality of methods to obtain the quality of the randomization of write data corresponding to first direction according to N state percentages. This is illustrated in the following specific examples:

(1) Method of comparing differences between maximum and minimum state percentages in each bit value group:

Processor 211 first calculates maximum differences of N state percentages in each bit value group:
1st bit value group: S0 percentage 37.5%, S1 percentage 62.5%, maximum difference =|62.5% 37.5%|=25%.
2nd bit value group: S0 percentage 50.0%, S1 percentage 50.0%, maximum difference =|50.0% 50.0%|=0%.
3rd bit value group: S0 percentage 50.0%, S1 percentage 50.0%, maximum difference =|50.0% 50.0%|=0%.
4th bit value group: S0 percentage 50.0%, S1 percentage 50.0%, maximum difference =|50.0% 50.0%|=0%.

Processor 211 may set a preset threshold, for example 20%. If the maximum differences of all bit value groups are all not greater than the threshold, the quality of the randomization of the write data corresponding to the first direction is determined to be qualified. In this example, since the maximum difference of 1st bit value group (25%) exceeds the preset threshold, the quality of the randomization is determined to be not qualified.

(2) State percentage interval distribution method: Processor 211 sets a plurality of interval ranges of state percentages, for example:

First interval: 0%~25%; second interval: 25%~50%; third interval: 50%~75%; fourth interval: 75%~100%.

Next, processor 211 counts distribution of state percentages of each bit value group falling in each interval:
1st bit value group: S0 (37.5%) falls in second interval, S1 (62.5%) falls in third interval.
2nd bit value group: S0 (50.0%) falls in third interval, S1 (50.0%) falls in third interval.
3rd bit value group: S0 (50.0%) falls in third interval, S1 (50.0%) falls in third interval.
4th bit value group: S0 (50.0%) falls in third interval, S1 (50.0%) falls in third interval.

Processor 211 may set one or more determination rules: for example, if more than a preset proportion (such as 75%) of the state percentages are all concentrated in the same interval, the quality of the randomization of the write data corresponding to the first direction is determined to be not qualified. In this example, 7 (out of 8 total) state percentages fall in the third interval, exceeding 75%, so the quality of the randomization is determined to be not qualified.

These methods may be used individually or in combination to evaluate the quality of the randomization of the write data corresponding to the first direction. Through this method, the present disclosure can effectively identify situations where bit state distributions are too concentrated or non-uniform. Through these different statistical methods, processor 211 can comprehensively evaluate the quality of the randomization of each write data.

### Embodiment 2: Introducing Baseline Percentage Value

In this embodiment, a concept of baseline percentage value is introduced and used to evaluate the quality of the randomization.

A baseline percentage value corresponding to a type of memory cell is 100% divided by a total number of corresponding bit states. For example, taking MLC (multi-level cell) as an example, X=2, N=2²=4, baseline percentage value is 100%/4=25%.

Initially, processor 211 obtains a plurality of bit values of write data. Here, assuming write data is “1001101110100011”.

Next, processor 211 obtains state percentages of N bit states. In this example, N=4, representing four bit states: 00, 01, 10, 11.

Next, processor 211 divides a number of each bit state by a total number of bits, and the result can be calculated as follows:
Percentage of bit state S0 (00): ⅜=37.5%;
Percentage of bit state S1 (01): 2/8=25%;
Percentage of bit state S2 (10): 2/8=25%;
Percentage of bit state S3 (11): ⅛=12.5%.

Next, processor 211 obtains baseline percentage value. Ideally, state percentages of each bit state among 4 bit states should be equal, i.e., 100%/4=25%.

The following illustrates specific details of obtaining the quality of the randomization of the write data corresponding to the first direction according to the N state percentages and the baseline percentage value.

In an embodiment, processor 211 obtains N deviation values between N state percentages of each bit value group and baseline percentage value. This is illustrated in the following specific examples:

Assuming that the write data corresponds to 4 bit value groups in first direction (M=4), each bit value group corresponds to two bit states (N=2), and baseline percentage value is 50%.

Processor 211 calculates N deviation values of 1st bit value group: Deviation value of bit state S0: |37.5%-50.0%|=12.5%; Deviation value of bit state S1: |62.5%-50.0%|=12.5%.

Processor 211 calculates N deviation values of 2nd bit value group: Deviation value of bit state S0: |50.0%-50.0%|=0%; Deviation value of bit state S1: |50.0%-50.0%|=0%.

Processor 211 calculates N deviation values of 3rd bit value group: Deviation value of bit state S0: |50.0%-50.0%|=0%; Deviation value of bit state S1: |50.0%-50.0%|=0%.

Processor 211 calculates N deviation values of 4th bit value group: Deviation value of bit state S0: |50.0%-50.0%|=0%; Deviation value of bit state S1: |50.0%-50.0%|=0%.

After obtaining these deviation values, processor 211 compares a deviation value of each bit state in M bit value groups to find maximum deviation values:
(1) For bit state S0: Since deviation values in M bit value groups are {12.5%, 0%, 0%, 0%}, maximum deviation value of S0 is 12.5%.
(2) For bit state S1: Since deviation values in M bit value groups are {12.5%, 0%, 0%, 0%}, maximum deviation value of bit state S1 is 12.5%.

Thus, processor 211 obtained N maximum deviation values corresponding to N bit states (e.g., in this example, N=2, 2 maximum deviation values corresponding to bit states S0, S1 are 12.5%, 12.5%). Assume preset threshold is 10%, since maximum deviation values of bit state S0 and bit state S1 (12.5%) are both greater than the preset threshold, the quality of the randomization of the write data corresponding to first direction is determined to be not qualified. This indicates that in first direction, there is at least one bit value group having an excessively non-uniform bit state distribution.

When the quality of the randomization of a write data is determined to be qualified, processor 211 may take this write data as target write data.

In an embodiment, after processor 211 obtains one target write data, randomization verification operations need not be performed on other write data, so as to save system resources.

However, in another embodiment, processor 211 may perform randomization verification operations on all write data to find write data with qualified and best quality of the randomization (e.g., smallest maximum deviation value) as target write data, so as to further improve reliability and security of data storage of storage device 20.

Please return to FIG. 2. After obtaining target write data, next, in step S240, processor 211 stores the target write data into a plurality of target memory cells among a plurality of memory cells of rewritable non-volatile memory module 220. More specifically, processor 211 assigns physical addresses of a plurality of target memory cells to the target write data, and after the target write data is programmed to the physical addresses, updates the corresponding mapping information. Furthermore, this process may involve wear leveling algorithms of flash controller, so as to ensure balanced usage times of memory cells and extend service life of storage device.

On the other hand, processor 211 generates and stores metadata related to target write data, these metadata are associated with subsequent read and recovery operations. In an embodiment, metadata includes one or more of the following:
a. Randomization algorithm identifier: Used to identify randomization algorithm used when generating target write data, for subsequent de-randomization operations.
b. Data mapping table: Records corresponding relationships between data blocks and physical memory cell addresses.
c. Error Correction Code (ECC): Used to detect and correct possible bit errors.
d. Timestamp: Records time of data writing, used for data version control and recovery.
e. Data length: Records length of original data, used for subsequent de-randomization operations.
f. Checksum: Used to verify data integrity.

In an embodiment, when memory controller 210 receives a read instruction from host system 10, processor 211 executes the following steps to recover original data:
(1) Parse read instructions: Processor 211 parses the read instruction from host system 10 to determine logical address range of data that need to be read.
(2) Address translation: Processor 211 uses logical-to-physical mapping table to convert logical addresses to corresponding physical addresses.
(3) Read metadata: Processor 211 first reads metadata related to target data. These metadata are typically stored in predefined special pages or blocks, including:
   a. Randomization algorithm identifier;
   b. Data mapping table;
   c. Error Correction Code (ECC);
   d. Data length;
   e. Checksum.
(4) Read randomized data: According to data mapping table in metadata, processor 211 reads randomized target write data from corresponding physical addresses.
(5) Error checking and correction: Processor 211 uses read ECC information to perform error checking on data. If correctable error are found, a correction is performed. If uncorrectable errors are found, the data block is marked as erroneous, and other recovery mechanisms are attempted.
(6) Data integrity verification: In an embodiment, processor 211 further uses stored checksum to verify integrity of read data. If verification fails, data recovery programs may need to be started or errors may be reported to host system.
(7) Determine de-randomization algorithm: After obtaining successfully decoded target write data, processor 211 determines de-randomization algorithm that needs to be used according to randomization algorithm identifier in metadata.
(8) Perform de-randomization operations: Processor 211 performs de-randomization operation on read randomized data. This process is a reverse process of the randomization operation during writing, and may include:
   a. Reverse shift operation;
   b. Reverse operations of XOR operation;
   c. Reverse permutation operation;
   d. Using the same random seeds for reverse operation.
(9) Data length adjustment: In an embodiment, processor 211 may further trim de-randomized data according to original data length recorded in metadata, so as to ensure that length of recovered data is consistent with original data.
(10) Data transmission: After obtaining corresponding original data, processor 211 transmits recovered original data to host system 10 via connection interface circuit 230 in response to the read instruction.

Through this detailed de-randomization process, memory controller 210 can accurately recover randomized target write data stored in storage device 20 to corresponding original data and safely transmit it to host system 10. This process not only ensures correct recovery of data, but also includes steps such as error detection, correction, and data integrity verification, so as to improve reliability and correctness of data reading. It should be noted that randomization operations and de-randomization operations may be implemented by the above-mentioned randomization/de-randomization algorithms via specific randomization circuits and de-randomization circuits. Furthermore, the randomization circuits and the de-randomization circuits may also be integrated as the same circuit unit.

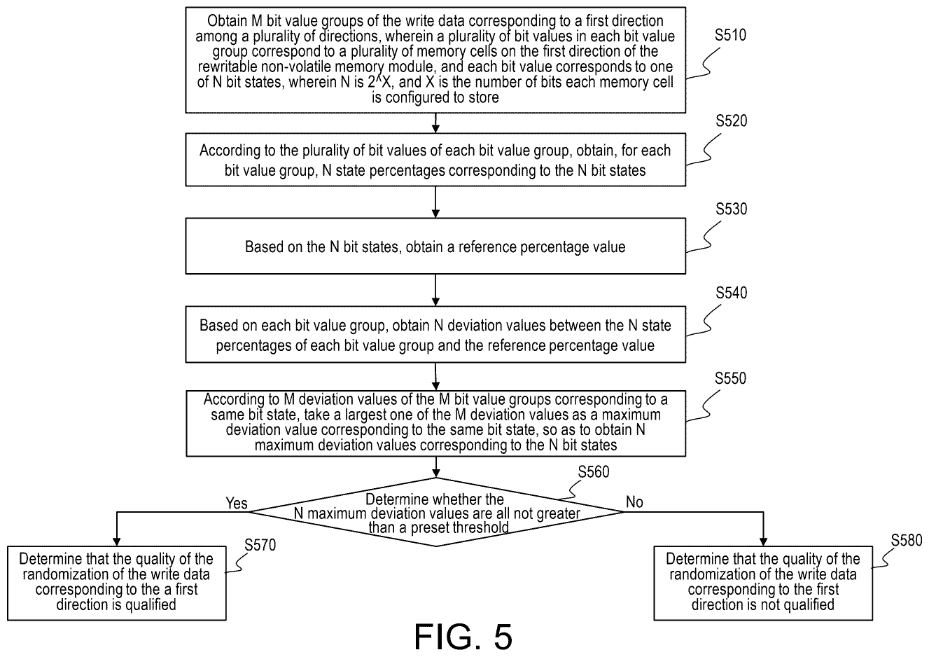

FIG. 5 is a flow chart of a randomization verification operation according to an embodiment of the present disclosure.

Please refer to FIG. 5, this embodiment describes a method for verifying the quality of the randomization of write data, adapted for a rewritable non-volatile memory module having a plurality of memory cells. The method is executed by a processor of a memory controller, mainly including the following steps:

In step S510, processor 211 obtains 4 bit value groups of write data corresponding to first direction (M=4). Since each memory cell can store 1 bit (X=1), each bit value corresponds to 2 bit states (N=2¹=2). Assume contents of these 4 bit value groups are:
First bit value group: “11100000”;
Second bit value group: “11110001”;
Third bit value group: “00011111”;
Fourth bit value group: “00001111”.

In step S520, processor 211 calculates the N bit state percentages of each bit value group:
(1) The N bit state percentages of first bit value group:
   Bit state S0 percentage: 62.5%;
   Bit state S1 percentage: 37.5%.
(2) The N bit state percentages of second bit value group:
   Bit state S0 percentage: 25.0%;
   Bit state S1 percentage: 75.0%.
(3) The N bit state percentages of third bit value group:
   Bit state S0 percentage: 37.5%;
   Bit state S1 percentage: 62.5%.
(4) The N bit state percentages of fourth bit value group:
   Bit state S0 percentage: 75.0%;
   Bit state S1 percentage: 25.0%.

Next, in step S530, processor 211 obtains baseline percentage value based on 2 bit states. In this example, baseline percentage value is 50% (100%/2=50%).

Next, in step S540, processor 211 calculates deviation values between each bit state in each bit value group and baseline percentage value:
(1) Deviation values of first bit value group:
   Deviation value of bit state S0: |62.5%-50.0%|=12.5%;
   Deviation value of bit state S1: |37.5%-50.0%|=12.5%.
:(2) Deviation values of second bit value group:
   Deviation value of bit state S0: |25.0%-50.0%|=25.0%;
   Deviation value of bit state S1: |75.0%-50.0%|=25.0%.
(3) Deviation values of third bit value group:
   Deviation value of bit state S0: |37.5%-50.0%|=12.5%;
   Deviation value of bit state S1: |62.5%-50.0%|=12.5%.
(4) Deviation values of fourth bit value group:
   Deviation value of bit state S0: |75.0%-50.0%|=25.0%;
   Deviation value of bit state S1: |25.0%-50.0%|=25.0%.

Next, in step S550, processor 211 calculates maximum deviation value of each bit state in 4 bit value groups:
4 deviation values of bit state S0 are {12.5%, 25.0%, 12.5%, 25.0%}: maximum deviation value of bit state S0 is 25.0%.
4 deviation values of bit state S1 are {12.5%, 25.0%, 12.5%, 25.0%}: maximum deviation value of bit state S1 is 25.0%.

Next, in step S560, processor 211 sets preset threshold to 20% and determines whether the 2 maximum deviation values are all not greater than the preset threshold.

In step S580, since maximum deviation values of bit state S0 and bit state S1 (25.0%) are respectively greater than preset threshold (20%), processor 211 determines that the quality of the randomization of the write data corresponding to first direction is not qualified.

Through the above method, the present disclosure can not only evaluate overall bit state distribution, but also identify serious deviations occurring in specific bit value groups. This detailed evaluation method helps to early detect data distribution problems that may cause storage reliability degradation, avoiding defects of traditional methods that only focus on overall statistics while ignoring local extreme situations.

In the following, a complete embodiment is used to further illustrate randomization verification operations of the present disclosure.

In an embodiment, randomization verification operations are illustrated using rewritable non-volatile memory module 220 of Triple-Level Cell (TLC) as an example. In TLC architecture, each memory cell is configured to store 3 bits (X=3), therefore there are 8 bit states (N=2³=8). Furthermore, it is further assumed that what is currently to be verified is 3 bit value groups of write data corresponding to first direction.

Processor 211 first obtains 8 bit state distributions of a plurality of memory cells of 1st bit value group of write data corresponding to first direction:

State percentage of bit state S0: 13.4%, state percentage of bit state S1: 11.8%, state percentage of bit state S2: 12.7%, state percentage of bit state S3: 13.1%, state percentage of bit state S4: 12.5%, state percentage of bit state S5: 11.7%, state percentage of bit state S6: 13.2%, state percentage of bit state S7: 11.6%.

Next, processor 211 first obtains 8 bit state distributions of a plurality of memory cells of 2nd bit value group of write data corresponding to first direction:

State percentage of bit state S0: 12.2%, state percentage of bit state S1: 12.4%, state percentage of bit state S2: 13.3%, state percentage of bit state S3: 12.1%, state percentage of bit state S4: 12.6%, state percentage of bit state S5: 12.0%, state percentage of bit state S6: 12.8%, state percentage of bit state S7: 12.6%.

Next, processor 211 first obtains 8 bit state distributions of a plurality of memory cells of 3rd bit value group of write data corresponding to first direction:

State percentage of bit state S0: 10.1%, state percentage of bit state S1: 13.8%, state percentage of bit state S2: 11.6%, state percentage of bit state S3: 14.1%, state percentage of bit state S4: 12.7%, state percentage of bit state S5: 12.2%, state percentage of bit state S6: 13.1%, state percentage of bit state S7: 12.4%.

Processor 211 uses baseline percentage value of 12.5% as reference to calculate deviation values of each bit state on each line. Taking bit state S0 as an example:
Deviation value of 1st bit value group corresponding to bit state S0: |13.4%-12.5%|=0.9%;
Deviation value of 2nd bit value group corresponding to bit state S0: |12.2%-12.5%|=0.3%;
Deviation value of 3rd bit value group corresponding to bit state S0: |10.1%-12.5%|=2.4%.

Next, processor 211 finds maximum deviation value of bit state S0 on all lines to be 2.4%. Assume preset threshold is 3%, since 2.4% is less than 3%, distribution of bit state S0 is qualified.

Processor 211 performs the same calculations and determinations for other bit states (S1 to S7). If maximum deviation values of all bit states are all less than preset threshold, the quality of the randomization of first direction is qualified (e.g., the randomization verification for the first direction is qualified). Next, processor 211 performs the same verification process for second direction and third direction.

This method particularly focuses on distribution situation of each bit state on each line, and can effectively avoid problems of traditional methods that only look at overall average values while ignoring local extreme distribution problems. Furthermore, by separately verifying distribution situations of three directions, the present disclosure can more comprehensively evaluate data distribution uniformity in a three-dimensional structure, improving storage reliability.

In the following, another example is used to further illustrate how to perform the randomization verification operations based on a plurality of directions of the three-dimensional circuit architecture.

In an embodiment, processor 211 first performs verification on first direction. Assume the write data has 4 bit value groups (M=4) in first direction, each group containing 8 memory cells. In this example, each memory cell is a single-level cell (SLC), therefore there are 2 bit states (N=2). When processor 211 calculates maximum deviation values of bit state S0 and bit state S1 to be 18% and 17% respectively, and preset threshold is 20%, the quality of the randomization of write data corresponding to first direction is determined to be qualified.

Next, processor 211 performs verification on second direction. Assume there are 3 bit value groups (P=3) in second direction, processor 211 calculates state percentages of each bit value group:
First bit value group: bit state S0 percentage: 45%; bit state S1 percentage: 55%.
Second bit value group: bit state S0 percentage: 52%; bit state S1 percentage: 48%.
Third bit value group: bit state S0 percentage: 47%; bit state S1 percentage: 53%.

Processor 211 calculates deviations from baseline percentage value of 50%:
3 deviation values of bit state S0 {5%, 2%, 3%}: maximum deviation value of bit state S0 is 5%; 3 deviation values of bit state S1 {5%, 2%, 3%}: maximum deviation value of bit state S1 is 5%.

Since both maximum deviation values are less than preset threshold of 20%, processor 211 determines that the quality of the randomization of second direction is qualified.

Finally, processor 211 performs verification on third direction. Assuming that there are 5 bit value groups (Q=5) in third direction, after similar calculation processes, the result are as follows: the maximum deviation value of bit state S0 is 15%; the maximum deviation value of bit state S1 is 16%.

These deviation values are also all less than preset threshold of 20%, therefore processor 211 determines that the quality of the randomization of third direction is qualified.

Since the qualities of the randomization of write data corresponding to all directions (i.e., the first direction, the second direction, and the third direction) are qualified, processor 211 finally determines that the quality of the randomization of the write data is qualified.

However, in another embodiment, assuming that there are 5 bit value groups (Q=5) in third direction, after similar calculation processes, the results are: the maximum deviation value of bit state S0 is 25%; the maximum deviation value of bit state S1 is 16%. Since the maximum deviation value of bit state S0 is greater than preset threshold of 20%, processor 211 determines that the quality of the randomization corresponding to third direction is not qualified.

This multi-direction verification method overcomes limitations of traditional technologies that only focus on single direction. By simultaneously verifying data distribution situations in three directions, the present disclosure can more comprehensively evaluate the degree of data randomization degree in a three-dimensional structure, effectively improving storage reliability.

In an embodiment, when processor 211 determines that the quality of the randomization of write data corresponding to first direction is not qualified, further measures are taken to record abnormal conditions.

Assuming that the write data corresponds to 4 bit value groups (M=4) in first direction, each group containing 8 memory cells, and they are single-level cells (SLC), so there are 2 bit states (N=2). Processor 211 has completed the calculations of the maximum deviation value of each bit state:
4 deviation values of bit state S0 {22%, 15%, 18%, 20%}: maximum deviation value of bit state S0 is 22%; 4 deviation values of bit state S1 {12%, 25%, 16%, 15%}: maximum deviation value of bit state S1 is 25%.

When preset threshold is set to 20%, processor 211 finds:
Maximum deviation value of bit state S0 (22%) >preset threshold (20%);
Maximum deviation value of bit state S1 (25%) >preset threshold (20%).

Therefore, processor 211 obtains these two abnormal maximum deviation values (22% and 25%), and corresponding abnormal bit states (bit state S0 and bit state S1).

Next, processor 211 records bit states whose maximum deviation values exceed preset threshold and their corresponding direction: first direction (such as X direction); and abnormal bit states in first direction (bit state S0 and bit state S1). In another embodiment, processor 211 further records corresponding maximum deviation values (e.g., 22% and 25%).

This recording mechanism enables the present disclosure to not only identify situations where the quality of the randomization is not qualified, but also accurately locate directions where a problem occurs and the specific bit states, which helps subsequent targeted improvements to the randomization operation.

In an embodiment, when processor 211 finds that the qualities of the randomizations of all write data are all not qualified, the randomization operation is adjusted according to the recorded abnormal bit states and their corresponding directions.

Assuming that the original data generates 3 write data after 3 different randomization operations, randomization verification results corresponding to first direction are as follows:
(1) First write data (generated via randomization operation using an XOR operation): maximum deviation value of bit state S0 is 25% (in second bit value group); maximum deviation value of bit state S1 is 23% (in third bit value group).
(2) Second write data (generated via randomization operation of shift operation): maximum deviation value of bit state S0 is 22% (in first bit value group); maximum deviation value of bit state S1 is 24% (in fourth bit value group).
(3) Third write data (generated via randomization operation of permutation operation): maximum deviation value of bit state S0 is 26% (in third bit value group); maximum deviation value of bit state S1 is 21% (in second bit value group).

Since the qualities of the randomizations of all write data in the first direction are all not qualified (maximum deviation values all exceed preset threshold of 20%), processor 211 may perform the following adjustments according to the recorded abnormal bit states and their distribution situations in the first direction, for example:
1. In response to the abnormality of bit state S0 in second bit value group of first write data, processor 211 adjusts random sequence of XOR operation in that region.
2. In response to the abnormality of bit state S1 in fourth bit value group of second write data, processor 211 increases number of shift operations in that region.
3. In response to the abnormality of bit state S0 in third bit value group of third write data, processor 211 adopts more complex permutation table for that region.

After adjustments, processor 211 regenerates write data and performs the randomization verification operations until target write data that passes verification is found.

After the above adjustments, processor 211 regenerates 3 new write data and performs the randomization verification operations again. If any of the new write data is qualified, processor 211 can use the qualified write data as target write data and store it into a plurality of target memory cells.

This adaptive adjustment mechanism enables the present disclosure to optimize randomization operations according to specific abnormal situations, not only improving success rate of obtaining qualified write data, but also effectively avoiding problems of repeatedly occurring non-uniform data distribution in specific directions or specific positions.

The present embodiment further provides a computer program product, including computer-readable code, or a non-volatile computer-readable storage medium carrying computer-readable code, when the computer-readable code runs in a processor of a storage device, the processor in the storage device executes steps of the above data writing method. The computer program product may be specifically implemented through hardware, firmware, software, or combinations thereof. In one alternative embodiment, the computer program product is specifically embodied as a computer storage medium, in another alternative embodiment, the computer program product is specifically embodied as a software product, such as Software Development Kit (SDK), etc.

The data writing method and its randomization verification operations provided by the present disclosure have significant technical effects in three-dimensional structure non-volatile memories. Through performing multiple randomization operations on write data and executing verification processes based on a plurality of directions of three-dimensional circuit architecture, the method can effectively improve distribution uniformity of data in memories.

Specifically, the method precisely quantifies the quality of the randomization of data by analyzing state percentages of a plurality of bit value groups in each direction and deviation values from baseline percentage value. By comparing maximum deviation values of each bit state in a plurality of bit value groups in the same direction with preset threshold, the present disclosure can accurately determine whether data distribution in each direction is uniform. Finally, only when the qualities of the randomizations of write data in three directions are all qualified, the write data is determined to be usable for storing original data.

When the quality of the randomization in a certain direction is found to be not qualified, the method records abnormal bit states whose deviation values exceed preset threshold in that direction. This targeted recording mechanism provides clear basis for subsequent adjustments to randomization operations. If the qualities of the randomizations of all write data are all not qualified, the method can adjust randomization operations according to recorded abnormal bit states and their corresponding directions, regenerate write data and perform verification again, so as to store qualified write data, thereby completing storage of original data.

Compared to traditional methods that only focus on overall data distribution, the present disclosure can more accurately evaluate the degree of the data randomization in a three-dimensional structure by analyzing local distribution characteristics of bit value groups in each direction. This multi-direction, multi-level verification method not only improves storage reliability, but also can effectively avoid problems of non-uniform data distribution occurring in specific directions or local regions.

It will be apparent to those skilled in the art that various modifications and variations can be made to the disclosed embodiments without departing from the scope or spirit of the present disclosure. In view of the foregoing, it is intended that the present disclosure covers modifications and variations provided that they fall within the scope of the following claims and their equivalents.

What is claimed is:

1. A data writing method, adapted for a rewritable non-volatile memory module having a plurality of memory cells, the data writing method comprising:
obtaining original data from a host system;
performing a plurality of randomization operations on the original data to obtain a plurality of write data;
based on a plurality of directions of a three-dimensional circuit architecture of the rewritable non-volatile memory module, performing a randomization verification operation on each write data to obtain a target write data from the plurality of write data, wherein a quality of randomization of the target write data is determined to be qualified; and
storing the target write data into a plurality of target memory cells among the plurality of memory cells.

2. The data writing method according to claim 1, wherein each randomization operation processes the original data by using a different randomization algorithm, wherein the different randomization algorithms comprise at least one of the following:
an XOR operation, performing an exclusive OR operation on the original data with a plurality of different predefined random sequences;
a shift operation, performing a plurality of different cyclic shifts or logical shifts on the original data;
a permutation operation, changing an order of bits in the original data according to a plurality of different predefined permutation tables;
a dynamic random seed operation, generating a plurality of different random seeds based on a system time, a data address, or other system variables, and using the plurality of random seeds and the original data to generate the plurality of write data; and
a grouping operation, dividing the original data into a plurality of sub-blocks, and applying the different XOR operations, the shift operations, the permutation operations, or the dynamic random seed operations to the plurality of sub-blocks.

3. The data writing method according to claim 1, wherein the step of performing the randomization verification operation on each write data based on the plurality of directions of the three-dimensional circuit architecture of the rewritable non-volatile memory module comprises:
obtaining M bit value groups of the write data corresponding to a first direction among the plurality of directions, wherein a plurality of bit values in each bit value group correspond to a plurality of memory cells on the first direction of the rewritable non-volatile memory module, and each bit value corresponds to one of N bit states, wherein N is 2^{X}, and X is the number of bits each memory cell is configured to store;
according to the plurality of bit values of each bit value group, obtaining, for each bit value group, N state percentages corresponding to the N bit states; and
according to the N state percentages, obtaining the quality of the randomization of the write data corresponding to the first direction.

4. The data writing method according to claim 3, wherein step of performing the randomization verification operation on each write data based on the plurality of directions of the three-dimensional circuit architecture of the rewritable non-volatile memory module further comprises:
based on the N bit states, obtaining a baseline percentage value; and
according to the N state percentages and the baseline percentage value, obtaining the quality of the randomization of the write data corresponding to the first direction.

5. The data writing method according to claim 4, wherein step of performing the randomization verification operation on each write data based on the plurality of directions of the three-dimensional circuit architecture of the rewritable non-volatile memory module further comprises:
based on each bit value group, obtaining N deviation values between the N state percentages of each bit value group and the baseline percentage value;
according to M deviation values of the M bit value groups corresponding to a same bit state, taking a largest one of the M deviation values as a maximum deviation value corresponding to the same bit state, so as to obtain N maximum deviation values of the M bit value groups that correspond to the N bit states;
if the N maximum deviation values are all not greater than a preset threshold, determining that the quality of the randomization of the write data corresponding to the first direction is qualified;
if one of the N maximum deviation values is greater than the preset threshold, determining that the quality of the randomization of the write data corresponding to the first direction is not qualified.

6. The data writing method according to claim 5, wherein the plurality of directions comprise the first direction, a second direction and a third direction, and step of performing the randomization verification operation on each write data based on the plurality of directions of the three-dimensional circuit architecture of the rewritable non-volatile memory module further comprises:
obtaining P bit value groups of the write data corresponding to the second direction and N maximum deviation values of the P bit value groups that correspond to the N bit states, to obtain the quality of the randomization of the write data corresponding to the second direction;
obtaining Q bit value groups of the write data corresponding to the third direction and N maximum deviation values of the Q bit value groups that correspond to the N bit states, to obtain the quality of the randomization of the write data corresponding to the third direction; and
if the qualities of the randomization of the write data corresponding to the first direction, the second direction, and the third direction are all qualified, determining that the quality of the randomization of the write data is qualified.

7. The data writing method according to claim 5, wherein after determining that the quality of the randomization of the write data corresponding to the first direction is not qualified, the method further comprises:
obtaining one or more abnormal maximum deviation values greater than the preset threshold among the N maximum deviation values and one or more abnormal bit states corresponding to the one or more abnormal maximum deviation values among the N bit states; and
recording the first direction and the one or more abnormal bit states corresponding to the first direction.

8. The data writing method according to claim 7, wherein if the qualities of the randomization of the plurality of write data are all not qualified, the method further comprises:
adjusting the plurality of randomization operations according to the one or more abnormal bit states and the corresponding direction, to regenerate a new plurality of write data; and
performing the randomization verification operation on each new write data again to attempt to obtain the target write data, and then storing the target write data into the plurality of target memory cells.

9. A memory controller, adapted for a storage device configured with a rewritable non-volatile memory module, wherein the storage device is electrically connected to a host system, wherein the memory controller comprises:
a memory interface control circuit, for electrically connecting to the rewritable non-volatile memory module, wherein the rewritable non-volatile memory module has a plurality of memory cells; and
a processor, electrically connected to the memory interface control circuit,
wherein the processor is configured to:
obtain original data from the host system;
perform a plurality of randomization operations on the original data to obtain a plurality of write data;
based on a plurality of directions of a three-dimensional circuit architecture of the rewritable non-volatile memory module, perform a randomization verification operation on each write data to obtain a target write data from the plurality of write data, wherein a quality of randomization of the target write data is determined to be qualified; and
store the target write data into a plurality of target memory cells among the plurality of memory cells.

10. The memory controller according to claim 9, wherein each randomization operation processes the original data by using a different randomization algorithm, wherein the different randomization algorithms comprise at least one of the following:
an XOR operation, performing an exclusive OR operation on the original data with a plurality of different predefined random sequences;
a shift operation, performing a plurality of different cyclic shifts or logical shifts on the original data;
a permutation operation, changing an order of bits in the original data according to a plurality of different predefined permutation tables;
a dynamic random seed operation, generating a plurality of different random seeds based on a system time, a data address, or other system variables, and using the plurality of random seeds and the original data to generate the plurality of write data; and
a grouping operation, dividing the original data into a plurality of sub-blocks, and applying the different XOR operations, the shift operations, the permutation operations, or the dynamic random seed operations to the plurality of sub-blocks.

11. The memory controller according to claim 9, wherein step of performing the randomization verification operation on each write data based on the plurality of directions of the three-dimensional circuit architecture of the rewritable non-volatile memory module comprises:
obtaining M bit value groups of the write data corresponding to a first direction among the plurality of directions, wherein a plurality of bit values in each bit value group correspond to a plurality of memory cells on the first direction of the rewritable non-volatile memory module, and each bit value corresponds to one of N bit states, wherein N is 2^{X}, and X is the number of bits each memory cell is configured to store;
according to the plurality of bit values of each bit value group, obtaining, for each bit value group, N state percentages corresponding to the N bit states;
according to the N state percentages, obtaining the quality of the randomization of the write data corresponding to the first direction.

12. The memory controller according to claim 11, wherein step of performing the randomization verification operation on each write data based on the plurality of directions of the three-dimensional circuit architecture of the rewritable non-volatile memory module further comprises:
based on the N bit states, obtaining a baseline percentage value; and
according to the N state percentages and the baseline percentage value, obtaining the quality of the randomization of the write data corresponding to the first direction.

13. The memory controller according to claim 12, wherein step of performing the randomization verification operation on each write data based on the plurality of directions of the three-dimensional circuit architecture of the rewritable non-volatile memory module further comprises:
based on each bit value group, obtaining N deviation values between the N state percentages of each bit value group and the baseline percentage value;
according to M deviation values of the M bit value groups corresponding to a same bit state, taking a largest one of the M deviation values as a maximum deviation value corresponding to the same bit state, so as to obtain N maximum deviation values of the M bit value groups that correspond to the N bit states;
if the N maximum deviation values are all not greater than a preset threshold, determining that the quality of the randomization of the write data corresponding to the first direction is qualified;
if one of the N maximum deviation values is greater than the preset threshold, determining that the quality of the randomization of the write data corresponding to the first direction is not qualified.

14. The memory controller according to claim 13, wherein the plurality of directions comprise the first direction, a second direction and a third direction, and step of performing the randomization verification operation on each write data based on the plurality of directions of the three-dimensional circuit architecture of the rewritable non-volatile memory module further comprises:
obtaining P bit value groups of the write data corresponding to the second direction and N maximum deviation values of the P bit value groups that correspond to the N bit states, to obtain the quality of the randomization of the write data corresponding to the second direction;
obtaining Q bit value groups of the write data corresponding to the third direction and N maximum deviation values of the Q bit value groups that correspond to the N bit states, to obtain the quality of the randomization of the write data corresponding to the third direction; and
if the qualities of the randomization of the write data corresponding to the first direction, the second direction, and the third direction are all qualified, determining that the quality of the randomization of the write data is qualified.

15. The memory controller according to claim 13, wherein after determining that the quality of the randomization of the write data corresponding to the first direction is not qualified, the processor is further configured to:
obtain one or more abnormal maximum deviation values greater than the preset threshold among the N maximum deviation values and one or more abnormal bit states corresponding to the one or more abnormal maximum deviation values among the N bit states; and
record the first direction and the one or more abnormal bit states corresponding to the first direction.

16. The memory controller according to claim 15, wherein if the qualities of the randomization of the plurality of write data are all not qualified, the processor is further configured to:
adjust the plurality of randomization operations according to the one or more abnormal bit states and the corresponding direction, to regenerate a new plurality of write data; and
perform the randomization verification operation on each new write data again to attempt to obtain the target write data, and then store the target write data into the plurality of target memory cells.
